(19) United States
(12) Patent Application Publication
(10) Pub. No.: US 2012/0247528 A1
(43) Pub. Date: Oct. 4, 2012

(54) THIN FILM PHOTOELECTRIC CONVERSION MODULE AND FABRICATION METHOD OF THE SAME

(75) Inventors: Chen-Pang FU, Taipei County (TW); Jia-Wei Ma, Taipei County (TW)

(73) Assignee: Du Pont Apollo Limited, Hong Kong (HK)

(21) Appl. No.: 13/076,441

(22) Filed: Mar. 31, 2011

(51) Int. Cl. H01L 31/05; H01L 31/18

(52) U.S. Cl. 136/244; 438/98; 257/E31.124

(57) ABSTRACT

A thin film photoelectric conversion module includes a substrate, a first electrode layer, at least one photoelectric conversion layer and a second electrode layer. The first electrode layer is deposited on the substrate, wherein the first electrode layer includes a plurality of first electrode rows extending along a current flow direction. Any immediately-adjacent two of the first electrode rows have a row of unoverlapped through holes formed therebetween. The photoelectric conversion layer is deposited on the first electrode layer. The second electrode layer is deposited on the photoelectric conversion layer.

### BACKGROUND

1. Field of Invention

The present disclosure relates to a photoelectric conversion apparatus. More particularly, the present disclosure relates to a thin film photoelectric conversion module and a fabrication method of the same.

2. Description of Related Art

A solar cell is a device that converts the energy of sunlight directly into electricity by the photovoltaic effect. In general, a thin film photoelectric conversion module includes a plurality of thin film photoelectric conversion cells connected to each other in series.

When a stain, such as a leaf or a bird dropping, is attached to the light-receiving surface of the thin film photoelectric conversion module, the light to the particular cell is partially or entirely intercepted by the stain so as to decrease the photoelectric motive force. The decreased photoelectric motive force acts as a diode connected in series in the reverse direction to the direction of the power generation. As a result, the light-intercepted cell exhibits a very high resistance, leading to the marked reduction in the output of the entire module. Further, the electrical current doesn't flow uniformly through the photoelectric conversion cells so as to bring about a local overheating called a hot spot phenomenon.

Accordingly, what is needed is an improved thin film photoelectric conversion module and its fabrication method that is able to reduce the effect of the hot spot phenomenon. The present disclosure addresses such a need.

### SUMMARY

It is therefore an objective of the present invention to provide an improved thin film photoelectric conversion module and its fabrication method that is able to reduce the effect of the hot spot phenomenon.

In accordance with the foregoing and other objectives of the present invention, a thin film photoelectric conversion module includes a substrate, a first electrode layer, at least one photoelectric conversion layer and a second electrode layer. The first electrode layer is deposited on the substrate, wherein the first electrode layer includes a plurality of first electrode rows extending along a current flow direction. Any immediately-adjacent two of the first electrode rows have a row of unoverlapped through holes formed therebetween. The photoelectric conversion layer is deposited on the first electrode layer. The second electrode layer is deposited on the photoelectric conversion layer.

In accordance with the foregoing and other objectives of the present invention, another thin film photoelectric conversion module includes a substrate, a first electrode layer, at least one photoelectric conversion layer and a second electrode layer. The first electrode layer is deposited on the substrate, wherein the first electrode layer includes a plurality of first electrode rows extending along a current flow direction. Any immediately-adjacent two of the first electrode rows have a row of unoverlapped through holes formed therebetween. A plurality of first grooves divide the first electrode layer into a plurality of first electrode columns along a direction which crosses the current flow direction. The photoelectric conversion layer is deposited on the first electrode layer. The photoelectric conversion layer includes a plurality of second grooves each formed next to one of the first grooves. The second electrode layer is deposited on the photoelectric conversion layer. The second electrode layer includes a plurality of third grooves each formed next to one of the second grooves.

According to an embodiment disclosed herein, the row of unoverlapped through holes have an average diameter or width ranging from about 30 μm to about 100 μm.

According to another embodiment disclosed herein, any immediately-adjacent two of the row of unoverlapped through holes have an interval therebetween ranging from about 1 percent to about 200 percent of the average diameter or width.

According to another embodiment disclosed herein, any immediately-adjacent two of the row of unoverlapped through holes have a resistance therebetween ranging from about 100 ohm to about 1 mega-ohm.

According to another embodiment disclosed herein, the row of unoverlapped through holes further extend through the photoelectric conversion layer and the second electrode layer.

According to another embodiment disclosed herein, each of the unoverlapped through holes is of a square, rectangular, circular or oval shape.

According to another embodiment disclosed herein, the substrate is a glass substrate, which includes a plurality of opaque materials each deposited to be aligned with each of the unoverlapped through holes.

According to another embodiment disclosed herein, the plurality of opaque materials are deposited on the same side of the glass substrate as the first electrode layer is deposited on.

According to another embodiment disclosed herein, the plurality of opaque materials are deposited on a side of the glass substrate, which is opposite to a side the first electrode layer is deposited on.

In accordance with the foregoing and other objectives of the present invention, a method for fabricating a thin film photoelectric conversion module includes the following steps. A first electrode layer is formed on a substrate. Multiple rows of unoverlapped through holes are formed to divide the first electrode layer into a plurality of first electrode rows extending along a current flow direction. At least one photoelectric conversion layer is formed on the first electrode layer. A second electrode layer is formed on the photoelectric conversion layer.

According to an embodiment disclosed herein, the unoverlapped through holes is formed to have an average diameter ranging from about 30 μm to about 100 μm.

According to another embodiment disclosed herein, the unoverlapped through holes is formed to have an interval therebetween ranging from about 1 percent to about 200 percent of the average diameter.

According to another embodiment disclosed herein, any immediately-adjacent two of the unoverlapped through holes is formed to have a resistance therebetween ranging from about 100 ohm to about 1 mega-ohm.

According to another embodiment disclosed herein, the unoverlapped through holes is formed to extend through the photoelectric conversion layer and the second electrode layer.

According to another embodiment disclosed herein, the unoverlapped through holes is formed by laser scribing, chemical etching, mechanical drilling or any combination thereof.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A illustrates a top view of a thin film photoelectric conversion module according to an embodiment of the present disclosure;

FIG. 1B illustrates a cross-sectional view taken along the line 1B-1B′ in FIG. 1A;

FIG. 1C and FIG. 1D illustrate two cross-sectional views of the thin film photoelectric conversion module according to another embodiment of the present disclosure;

FIG. 1E illustrates a cross-sectional view of the thin film photoelectric conversion module according to still another embodiment of the present disclosure;

FIGS. 1F-1H respectively illustrate an enlarged view of the section 160 as illustrated in FIG. 1A;

FIG. 2 illustrates a partial top view of the thin film photoelectric conversion module according to an embodiment of the present disclosure;

FIG. 3A illustrates a cross-sectional view taken along the line 3A-3A′ in FIG. 2;

FIG. 3B illustrates a cross-sectional view taken along the line 3B-3B′ in FIG. 2;

FIG. 3C illustrates a cross-sectional view taken along the line 3C-3C′ in FIG. 2;

FIG. 3D illustrates a cross-sectional view taken along the line 3D-3D′ in FIG. 2; and

FIG. 4 illustrates a flow chart of the method to fabricate a thin film photoelectric conversion module in an embodiment of the present disclosure.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

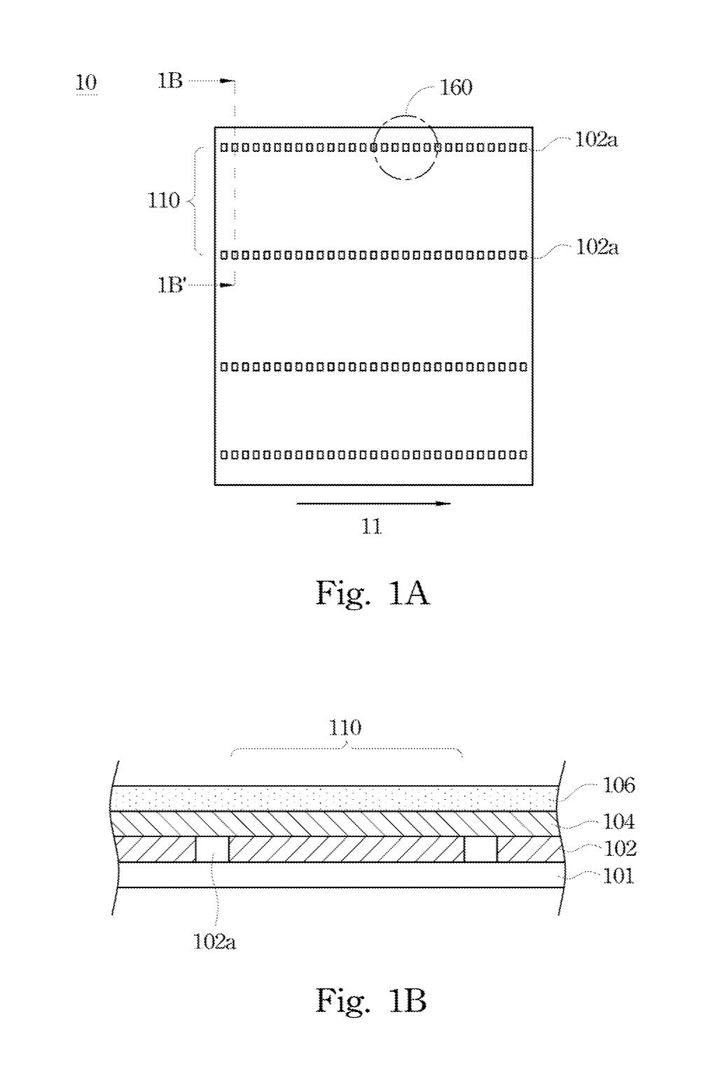

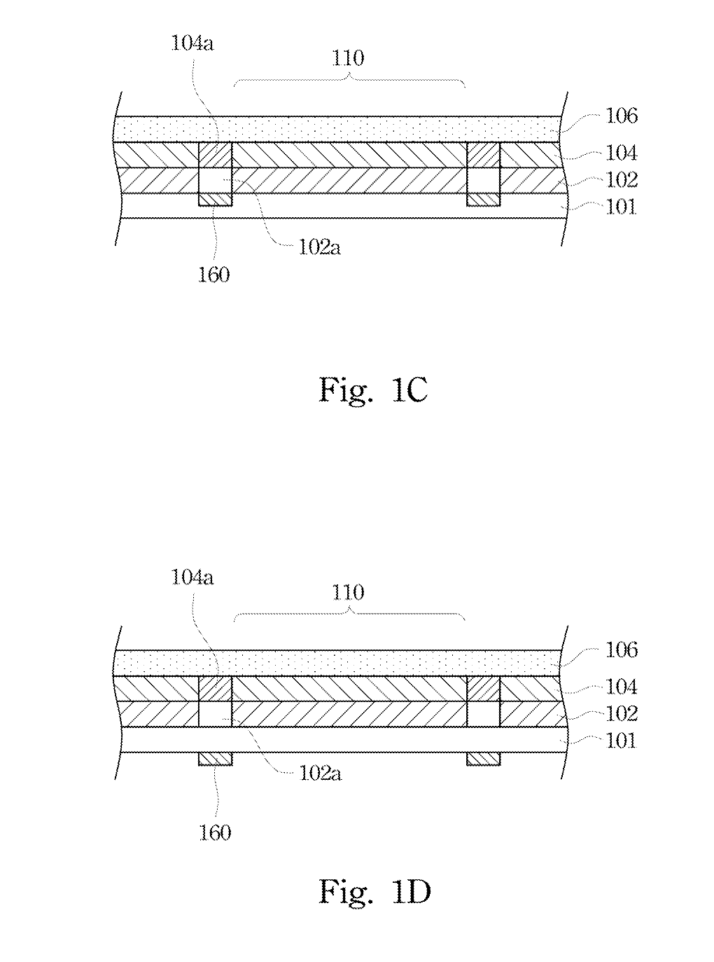

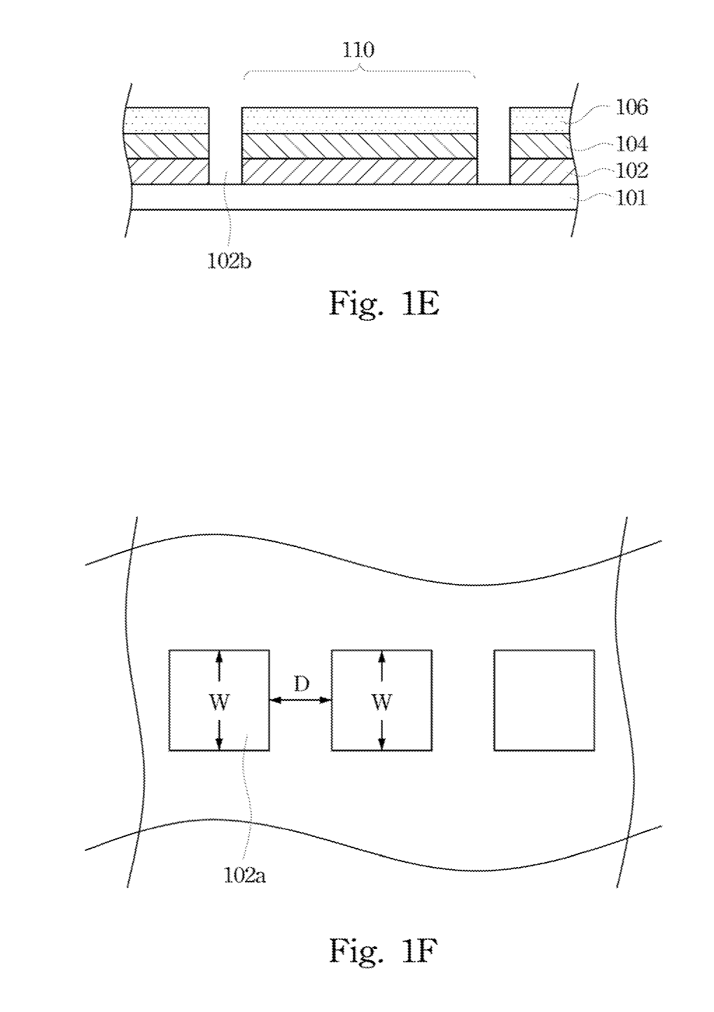

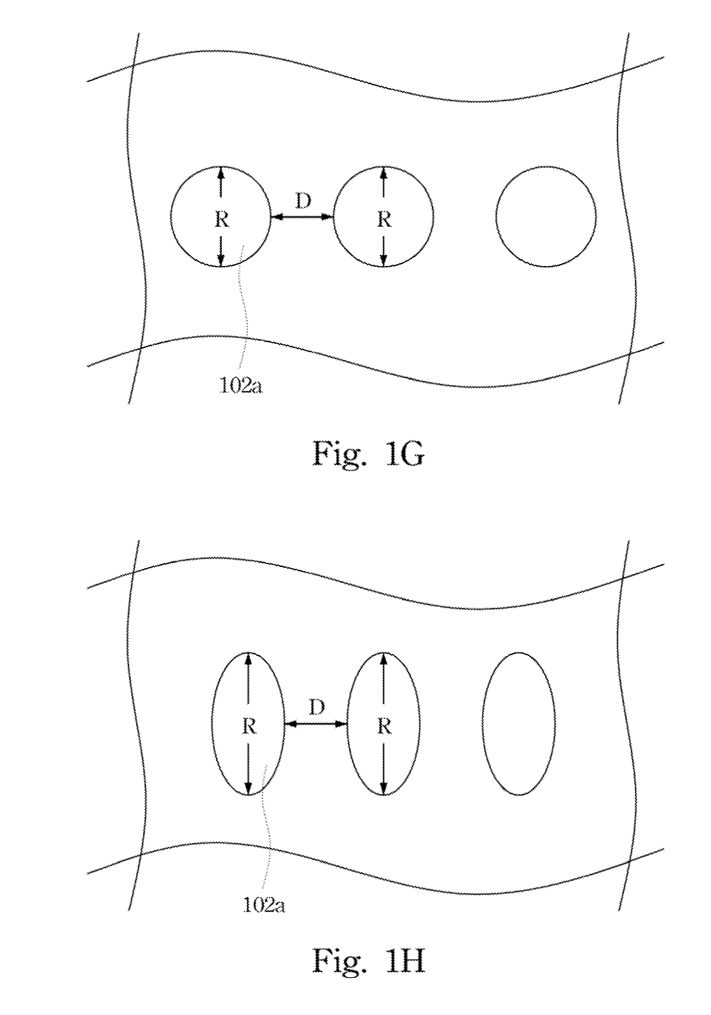

Please, refer to both FIG. 1A and FIG. 1B, wherein FIG. 1A illustrates a top view of a thin film photoelectric conversion module according to an embodiment of the present disclosure, and FIG. 1B illustrates a cross-sectional view taken along the line 1B-1B′ in FIG. 1A.

The thin film photoelectric conversion module 10 includes a substrate 101, a first electrode layer 102, a photoelectric conversion layer 104 and a second electrode layer 106 sequentially. The first electrode layer 102 includes a plurality of first electrode rows 110. A row of unoverlapped through holes 102a is formed between any immediately-adjacent two of the first electrode rows 110 to serve as a border therebetween. The first electrode rows 100 are substantially physically parallel to each other along a current flow direction, i.e. a horizontal direction 11 illustrated in FIG. 1A. The current flow direction is a direction that the current flows in an operating thin film photoelectric conversion module 10. In this embodiment, the first electrode layer 110 is a front electrode of the photoelectric conversion module 10.

The row of unoverlapped through holes 102a are formed substantially along a straight line as if a resistance wall is formed between any immediately-adjacent two of the first electrode rows 110. Due to the resistance wall between any immediately-adjacent two of the first electrode rows 110, the electrical currents would not or hardly cross the resistance wall. Therefore, the electrical currents in the thin film photoelectric conversion module 10 can distribute along different rows, thereby avoiding the chances of overheat condition caused by larger electrical currents.

In this embodiment, the first electrode layer 102 and the second electrode layer 106 can be a transparent conducting oxide layer or a metal layer according to designs. The substrate 101 next to the first electrode layer 102 can be made of a transparent material, such as glass.

Please refer to FIG. 1C and FIG. 1D, which illustrate two cross-sectional views of the thin film photoelectric conversion module according to another embodiment of the present disclosure. In this embodiment, the substrate 101 of the thin film photoelectric conversion module 10 is a glass substrate. The substrate 101 further includes a plurality of opaque materials 160 each deposited to be aligned with each of the rows of unoverlapped through holes 102a, which are used to prevent the sunlight from transmitting into the module 10, so as to make the corresponding positions of the photoelectric conversion layer 104 underneath become high resistance structures 104a. Therefore, the electrical current distributing mechanism along different rows is further reinforced due to the presence of the opaque materials 160. The opaque materials 160 can be deposited on either side of the substrate 101. As illustrated in FIG. 1C, the opaque materials 160 are deposited on the same side of the glass substrate 101 as the first electrode layer 102 is deposited on. As illustrated in FIG. 1D, the opaque materials 160 are deposited on a side of the glass substrate 101, which is opposite to a side the first electrode layer 102 is deposited on.

Refer to FIG. 1E, which illustrates a cross-sectional view of the thin film photoelectric conversion module according to still another embodiment of the present disclosure. This embodiment is slightly different from the embodiment of FIG. 1B in that each of the unoverlapped through holes 102b further extends through the photoelectric conversion layer 104 and the second electrode layer 106. In this embodiment, multiple rows of unoverlapped through holes 102b are formed after three layers (102, 104, 106) are deposited on the substrate 101. In the embodiment of FIG. 1B, multiple rows of through holes 102a are formed right after the first electrode layer 102 is deposited on the substrate 101.

In this embodiment, the multiple rows of unoverlapped through holes (102a or 102b) are formed by laser scribing, e.g. using infrared or ultraviolet laser to blast from the substrate 101. In an alternate embodiment, the multiple rows of unoverlapped through holes (102a or 102b) can be formed by chemical etching or mechanical drilling.

FIGS. 1F-1H respectively illustrate an enlarged view of the section 160 as illustrated in FIG. 1A. Refer to FIG. 1F, unoverlapped square or rectangular holes 102a are formed with an average inner width (W) ranging from about 30 μm to about 100 μm. Any immediately-adjacent two unoverlapped through holes 102a have an interval (D) therebetween ranging from about 1 percent to about 200 percent of the average width (W). Due to the interval (D) therebetween, any immediately-adjacent two unoverlapped through holes 102a have a resistance therebetween ranging from about 100 ohm to about 1 mega-ohm.

Refer to FIG. 1G, unoverlapped circular holes 102a are formed with an average diameter (R) ranging from about 30 μm to about 100 μm. Any immediately-adjacent two unoverlapped through holes 102a have an interval (D) therebetween ranging from about 1 percent to about 200 percent of the diameter (R). Due to the interval (D) therebetween, any immediately-adjacent two unoverlapped through holes 102a have a resistance therebetween ranging from about 100 ohm to about 1 mega-ohm.

Refer to FIG. 1H, unoverlapped oval holes 102a are formed with an average diameter (R) ranging from about 30 μm to about 100 μm. Any immediately-adjacent two unoverlapped through holes 102a have an interval (D) therebetween ranging from about 1 percent to about 200 percent of the diameter (R). Due to the interval (D) therebetween, any immediately-adjacent two unoverlapped through holes 102a have a resistance therebetween ranging from about 100 ohm to about 1 mega-ohm.

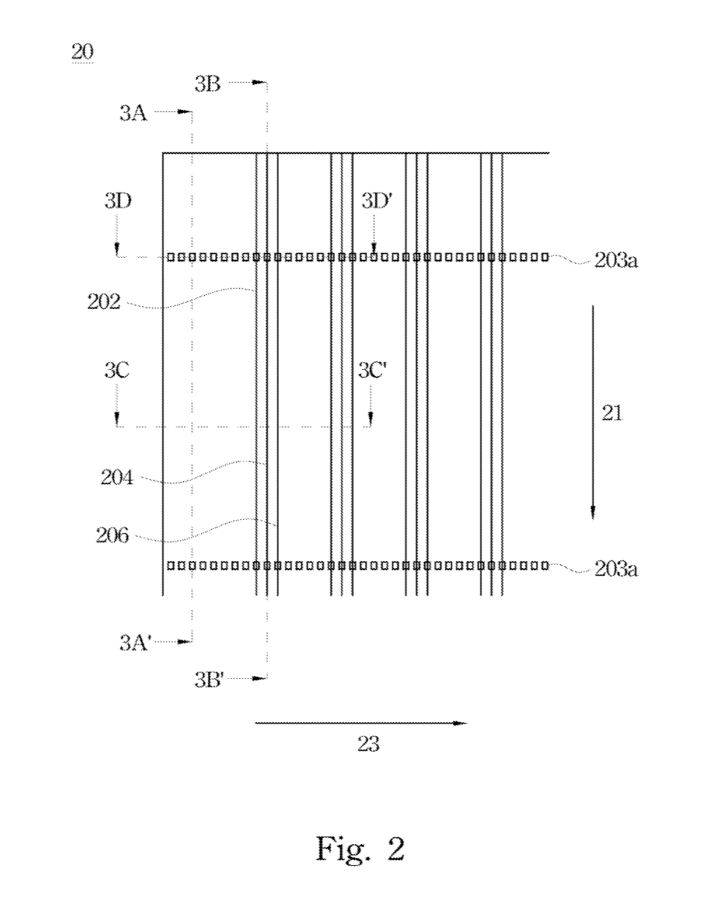

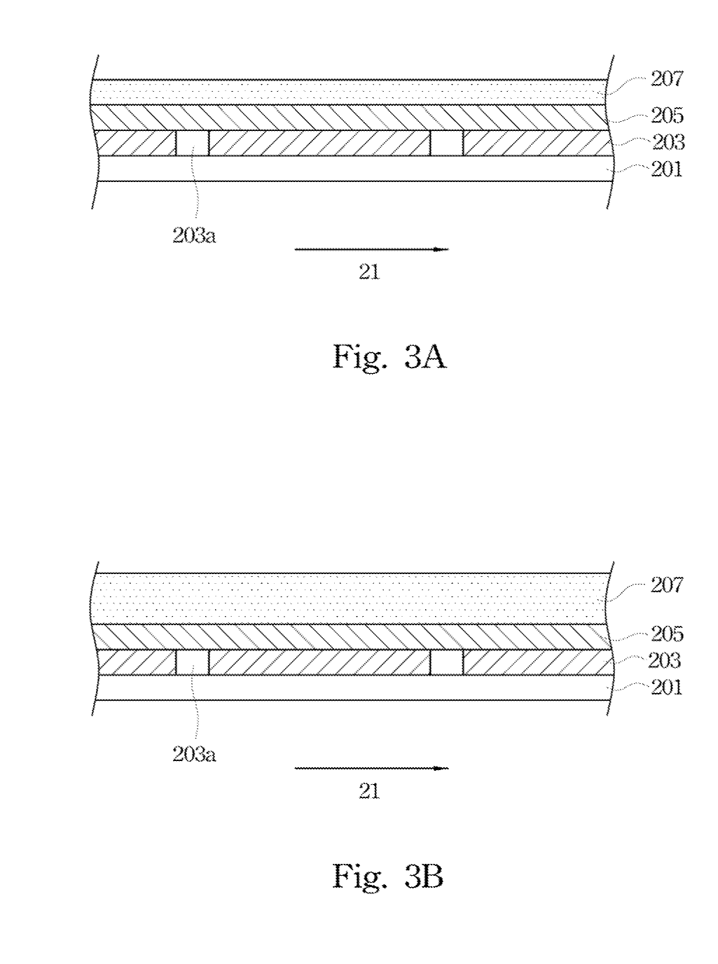

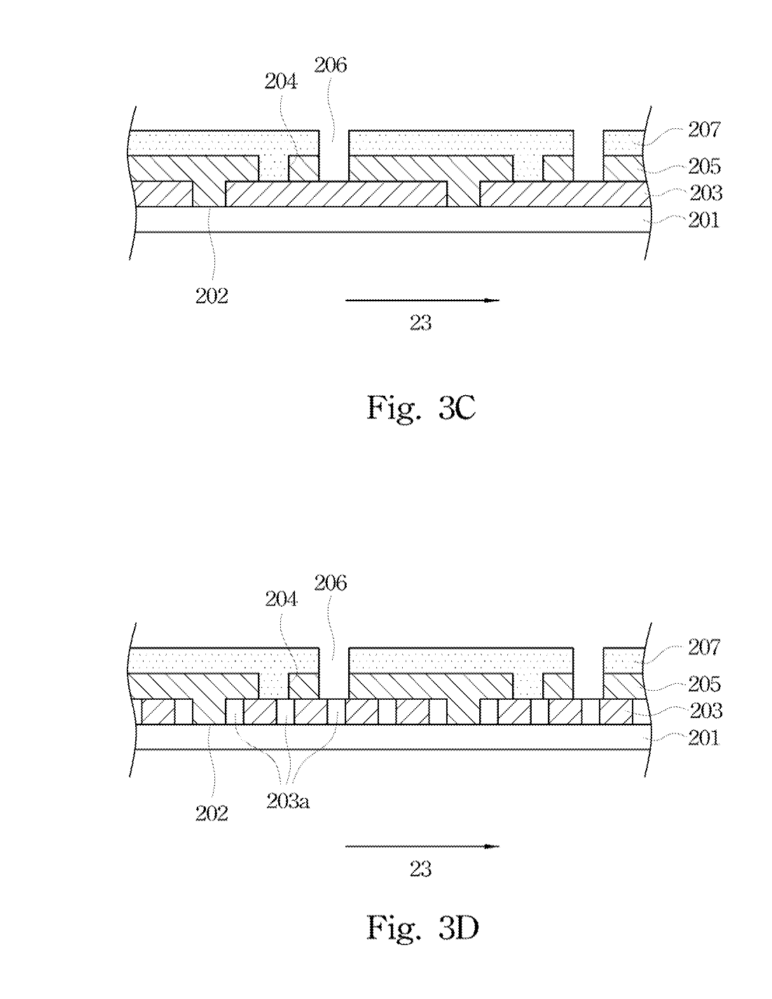

Please refer to FIG. 2 and FIG. 3A to FIG. 3D, wherein FIG. 2 illustrates a partial top view of the thin film photoelectric conversion module according to an embodiment of the present disclosure, and FIG. 3A to FIG. 3D illustrate the partial cross-sectional views taken along the lines (3A-3A′), (3B-3B′), (3C-3C′) and (3D-3D′) in FIG. 2A respectively.

Refer to FIG. 2, FIG. 3C and FIG. 3D, the thin film photoelectric conversion module 20 includes a substrate 201, a first electrode layer 203, a photoelectric conversion layer 205 and a second electrode layer 207 sequentially. The first electrode layer 203 includes a plurality of first grooves 202 to divide the first electrode layer 203 into a plurality of first electrode columns along a direction 21, which crosses the current flow direction 23.

The first electrode layer 203 further includes multiple rows of unoverlapped through holes 203a, wherein each row traverses the plurality of first grooves 202 to further divide the first electrode layer 203 into a plurality of first electrode rows, as illustrated in FIG. 2, FIG. 3A and FIG. 3B. In other words, the multiple rows of unoverlapped through holes 203a establish the borders of the first electrode rows. In an embodiment, the multiple rows of unoverlapped through holes 203a and the first grooves 202 are substantially perpendicular to each other. The term “substantially perpendicular” used herein means that the multiple rows of unoverlapped through holes 203a and the first grooves 202 are intersected to have an included angle slightly different from 90 degrees.

The photoelectric conversion layer 205 includes a plurality of second grooves 204 each formed substantially parallel and next to one of the first grooves 202. The second electrode layer 207 and the photoelectric conversion layer 205 includes a plurality of third grooves 206 penetrating through therein, wherein each of the third grooves 206 is formed substantially parallel and next to one of the second grooves 204. Besides, each second groove 204 is located between each first groove 202 and each third groove 206.

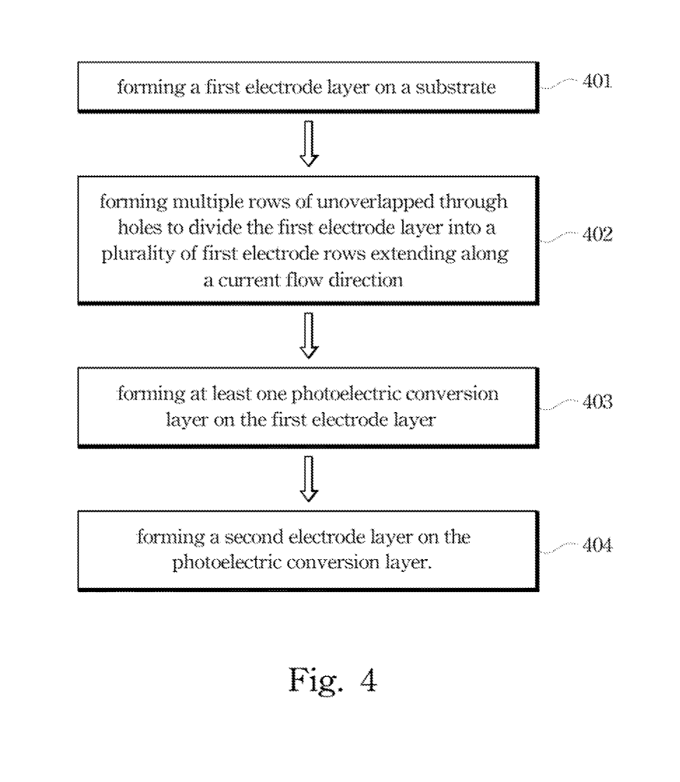

Please refer to FIG. 4, which illustrates a flow chart of the method to fabricate a thin film photoelectric conversion module 10, as depicted in FIG. 1A and FIG. 1B. The fabricating method comprises the following steps.

In step 401, a first electrode layer 102 is formed on a substrate 101. Then in step 402, multiple rows of unoverlapped through holes 102a are formed to divide the first electrode layer 102 into a plurality of first electrode rows 110 extending along a current flow direction 11. In step 403, a photoelectric conversion layer 104 is deposited on the first electrode layer 102. A second electrode layer 106 is further deposited on the photoelectric conversion layer 104 in step 404.

In an alternate embodiment (refer to FIG. 1E), the multiple rows of unoverlapped through holes 102b can be formed after three layers (102, 104, 106) are formed. In this case, each of the unoverlapped through holes 102b extends through three layers (102, 104, 106).

In this embodiment, the multiple rows of unoverlapped through holes (102a or 102b) are formed by laser scribing, e.g. using infrared (e.g. 1064 nm) or ultraviolet (e.g. 326 nm) laser to blast from the substrate 101. In an alternate embodiment, the multiple rows of unoverlapped through holes (102a or 102b) can be formed by chemical etching or mechanical drilling.

It's noticed that all the processes to form unoverlapped through holes or (first, second or third) grooves described above can be implemented by, but not limited thereto, laser-scribing processes, chemical etching processes or mechanical drilling. Further, the above-mentioned steps are not recited in the sequence in which the steps are performed. That is, unless the sequence of the steps is expressly indicated, the sequence of the steps is interchangeable, and all or part of the steps may be simultaneously, partially simultaneously, or sequentially performed.

According to the above-discussed embodiments, the thin film photoelectric conversion module and its manufacturing process are able to reduce the effect of the hot spot phenomenon by forming multiple rows of unoverlapped through holes at least on the electrode layer to further divide the electrode layer into multiple electrode rows.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film photoelectric conversion module comprising:
a substrate;
a first electrode layer deposited on the substrate, wherein the first electrode layer comprises a plurality of first electrode rows extending along a current flow direction, any immediately-adjacent two of the first electrode rows comprises a row of unoverlapped through holes formed therebetween;
at least one photoelectric conversion layer deposited on the first electrode layer; and
a second electrode layer deposited on the photoelectric conversion layer.

2. The thin film photoelectric conversion module of claim 1, wherein the row of unoverlapped through holes have an average diameter or width ranging from about 30 μm to about 100 μm.

3. The thin film photoelectric conversion module of claim 2, wherein any immediately-adjacent two of the row of unoverlapped through holes have an interval therebetween ranging from about 1 percent to about 200 percent of the average diameter or width.

4. The thin film photoelectric conversion module of claim 1, wherein any immediately-adjacent two of the row of unoverlapped through holes have a resistance therebetween ranging from about 100 ohm to about 1 mega-ohm.

5. The thin film photoelectric conversion module of claim 1, wherein the row of unoverlapped through holes further extend through the photoelectric conversion layer and the second electrode layer.

6. The thin film photoelectric conversion module of claim 1, wherein each of the unoverlapped through holes is of a square, rectangular, circular or oval shape.

7. The thin film photoelectric conversion module of claim 1, wherein the substrate is a glass substrate, further comprising a plurality of opaque materials each deposited to be aligned with each of the unoverlapped through holes.

8. The thin film photoelectric conversion module of claim 7, wherein the plurality of opaque materials are deposited on the same side of the glass substrate as the first electrode layer is deposited on.

9. The thin film photoelectric conversion module of claim 7, wherein the plurality of opaque materials are deposited on a side of the glass substrate, which is opposite to another side the first electrode layer is deposited on.

10. A thin film photoelectric conversion module comprising:
a substrate:
a first electrode layer formed on the substrate, wherein the first electrode layer comprises a plurality of first electrode rows and extending along a current flow direction, any immediately-adjacent two of the first electrode rows comprises a row of unoverlapped through holes formed therebetween, a plurality of first grooves separating the first electrode layer into a plurality of first electrode columns along a direction which crosses the current flow direction;
at least one photoelectric conversion layer deposited on the first electrode layer, wherein the photoelectric conversion layer comprises a plurality of second grooves each formed next to one of the first grooves; and
a second electrode layer deposited on the photoelectric conversion layer, wherein the second electrode layer comprises a plurality of third grooves each formed next to one of the second grooves.

11. The thin film photoelectric conversion module of claim 10, wherein the row of unoverlapped through holes have an average diameter ranging from about 30 μm to about 100 μm.

12. The thin film photoelectric conversion module of claim 11, wherein any immediately-adjacent two of the row of unoverlapped through holes have an interval therebetween ranging from about 1 percent to about 200 percent of the average diameter.

13. The thin film photoelectric conversion module of claim 10, wherein any immediately-adjacent two of the row of unoverlapped through holes have a resistance therebetween ranging from about 100 ohm to about 1 mega-ohm.

14. The thin film photoelectric conversion module of claim 10, wherein the row of unoverlapped through holes further extend through the photoelectric conversion layer and the second electrode layer.

15. The thin film photoelectric conversion module of claim 10, wherein each of the unoverlapped through holes is of a square, rectangular, circular or oval shape.

16. A method for fabricating a thin film photoelectric conversion module comprising the steps of:
forming a first electrode layer on a substrate;
forming multiple rows of unoverlapped through holes to divide the first electrode layer into a plurality of first electrode rows extending along a current flow direction;
forming at least one photoelectric conversion layer on the first electrode layer; and
forming a second electrode layer on the photoelectric conversion layer.

17. The method of claim 16, wherein the unoverlapped through holes is formed to have an average diameter ranging from about 30 μm to about 100 μm.

18. The method of claim 17, wherein the unoverlapped through holes is formed to have an interval therebetween ranging from about 1 percent to about 200 percent of the average diameter.

19. The method of claim 16, wherein any immediately-adjacent two of the unoverlapped through holes is formed to have a resistance therebetween ranging from about 100 ohm to about 1 mega-ohm.

20. The method of claim 16, wherein the unoverlapped through holes is formed to extend through the photoelectric conversion layer and the second electrode layer.

21. The method of claim 16, wherein the unoverlapped through holes is formed by laser scribing, chemical etching, mechanical drilling or any combination thereof.
